(19) United States
(12) Patent Application Publication
(10) Pub. No.: US 2026/0009820 A1
(43) Pub. Date: Jan. 8, 2026

(54) PROBE IMPLANTING EQUIPMENT

(71) Applicant: SILICONWARE PRECISION INDUSTRIES CO., LTD., Taichung City (TW)

(72) Inventors: Ping-Lin CHANG, Taichung City (TW); Chun-Wei FANG, Taichung City (TW); Chun-Yu HSIEH, Taichung City (TW); Yi-Ren CHEN, Taichung City (TW); Hung-Chieh YEH, Taichung City (TW)

(21) Appl. No.: 18/808,770

(22) Filed: Aug. 19, 2024

(30) Foreign Application Priority Data
Jul. 4, 2024 (TW) 113125132

(51) Int. Cl. G01R 1/04; G01R 31/28

(52) U.S. Cl. CPC G01R 1/0466; G01R 31/2891

(57) ABSTRACT

A probe implanting equipment including: a base; a test socket disposed on the base and having a plurality of positioning holes; a mouthpiece configuration configured for providing a plurality of probes to the plurality of positioning holes; and a vibration device disposed on the base for effectively positioning the probes in the positioning holes of the test socket via vibration.

### CROSS-REFERENCE TO RELATED APPLICATIONS

The present application is based upon and claims the right of priority to TW patent application No. 113125132, filed Jul. 4, 2024, the disclosure of which is hereby incorporated by reference herein in its entirety for all purposes.

### BACKGROUND

### 1. Technical Field

The present disclosure relates to a semiconductor testing equipment, and more particularly, to a probe implanting equipment for electrical testing of a semiconductor device.

### 2. Description of Related Art

In electrical testing of semiconductors, the object to be tested, such as a semiconductor package or a chip, is often placed into a test socket with multiple probes. After each probe contacts with the electrical connection pads or solder balls of the object to be tested, the test signal is transmitted to the object to be tested via each probe to achieve the purpose of testing.

To improve the speed of the test operation, the semiconductor industry has developed a probe implanting equipment to implant multiple probes into a test socket. However, during the probe implanting process, problems such as probe stuck and implanted probe deviation may easily occur, such that not all probes can be effectively implanted into the test socket. Consequently, more manpower and time are required for troubleshooting, causing the progress of the test operation to seriously slow down.

Therefore, how to overcome the above-mentioned problems of the prior art has become an urgent issue to be solved.

### SUMMARY

In view of the various deficiencies of the prior art, the present disclosure provides a probe implanting equipment, which comprises: a base; a test socket disposed on the base and having a plurality of positioning holes; a mouthpiece configuration configured for providing a plurality of probes to the plurality of positioning holes; and a vibration device disposed on the base.

In the aforementioned probe implanting equipment, the test socket has a first surface and a second surface opposite to the first surface, and the second surface is fixed on the base.

In the aforementioned probe implanting equipment, the mouthpiece configuration provides the plurality of probes to the plurality of positioning holes of the test socket by air blowing and probe throwing.

In the aforementioned probe implanting equipment, the probe implanting equipment further comprises a vibration controller for controlling an action of the vibration device.

In the aforementioned probe implanting equipment, the vibration controller and the vibration device are integrated with each other or are disposed independently of each other.

In the aforementioned probe implanting equipment, a user sets multiple control modes by the vibration controller according to a length of the probe or a diameter of the probe of the plurality of probes used to implant into the test socket.

In the aforementioned probe implanting equipment, the vibration controller selects different voltages according to the length of the probe to control the vibration device to vibrate.

In the aforementioned probe implanting equipment, the vibration controller selects different amplitudes according to the length of the probe to control the vibration device to vibrate.

In the aforementioned probe implanting equipment, the vibration controller selects different frequencies according to the diameter of the probe to control the vibration device to vibrate.

In the aforementioned probe implanting equipment, the vibration controller selects different vibration speeds according to the diameter of the probe to control the vibration device to vibrate.

Therefore, the probe implanting equipment of the present disclosure mainly dispose a vibration device (and a vibration controller) on the base connected to the test socket to effectively position the probes in the positioning holes of the test socket via the vibration, so as to avoid abnormal quality of manual probe implantation and abnormal problems such as probe stuck and implanted probe deviation, thereby achieving the purpose of manufacturing automation.

### BRIEF DESCRIPTION OF THE DRAWINGS

FIG. 1 is a schematic view of a probe implanting equipment according to the present disclosure.

### DETAILED DESCRIPTIONS

The following describes the implementation of the present disclosure with examples. Those skilled in the art can easily understand other advantages and effects of the present disclosure from the contents disclosed in this specification.

It should be understood that, the structures, ratios, sizes, and the like in the accompanying FIGURES are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “on,” “first,” “second,” “one,” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

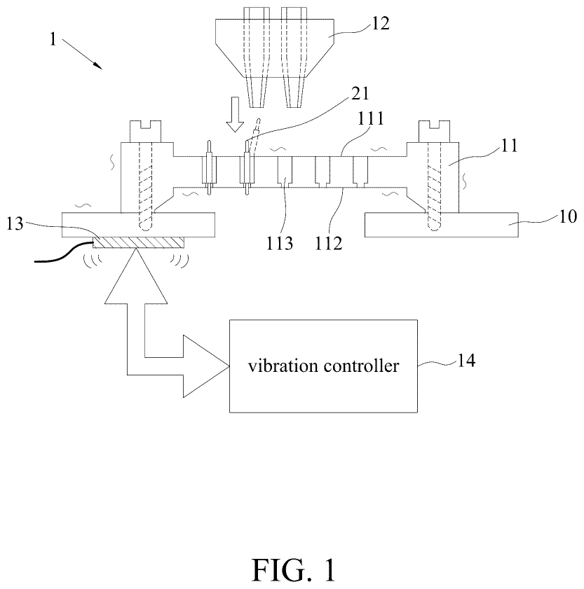

FIG. 1 is a schematic view of a probe implanting equipment according to the present disclosure. A probe implanting equipment 1 of this embodiment includes: a base 10, a test socket 11, a mouthpiece configuration 12 and a vibration device 13.

The test socket 11 has a first surface 111 and a second surface 112 opposite to the first surface 111 and a plurality of positioning holes 113 connecting the first surface 111 and the second surface 112.

The test socket 11 is disposed on the base 10 with the second surface 112, and can be locked on the base 10 via fasteners such as screws and bolts. Further, other fixing ways for combining the test socket 11 and the base 10 are also available, and are not limited thereto.

An object to be tested of a semiconductor device (such as a semiconductor package or a chip) can be placed on the first surface 111 of the test socket 11 for subsequent electrical testing of the object to be tested.

The mouthpiece configuration 12 provides a plurality of probes 21 into the plurality of positioning holes 113 of the test socket 11 by blowing air and throwing the probes.

The vibration device 13 is disposed on the base 10 and is used to provide vibrations to the test socket 11, and thus the probes 21 can be effectively placed in the positioning holes 113.

In addition, the probe implanting equipment 1 further includes a vibration controller 14 for controlling an action of the vibration device 13.

The vibration controller 14 can be a chip (circuits), a software (programs) or a hardware (devices), etc., and the vibration controller 14 can be integrated with the vibration device 13 or set up independently of each other.

An user can set multiple control modes by the vibration controller 14 according to the length of the probe or the diameter of the probe of each of the probes 21 used to implant the test socket 11.

For example, the vibration controller 14 can select different voltages according to the length of the probe of the probe (for example: a length of the probe of 3.0 mm corresponds to a voltage of 65V-75V), select different amplitudes according to the length of the probe of the probe, select different frequencies according to the diameter of the probe of the probe (for example: a diameter of the probe of 0.27 mm corresponds to a frequency of 255 Hz-265 Hz); or select different vibration speeds according to the diameter of the probe of the probe, so as to control the vibration device 13 to vibrate, thereby the probes 21 are effectively positioned in the positioning holes 113 of the test socket 11.

In practical applications, the user can first select the probe specifications and types according to the type of object to be tested of the semiconductor package or chip. Then, via the vibration controller 14, the voltage, amplitude, frequency, vibration speed, etc. are selected according to the length of the probe or the diameter of the probe of the selected probe to set the control mode, so that the mouthpiece configuration 12 provides the plurality of probes 21 to the plurality of positioning holes 113 of the test socket 11 by blowing and throwing probes. Finally, the vibration controller 14 controls the vibration device 13 to vibrate according to the aforementioned control mode, thereby providing vibrations to the test socket 11, thereby the probes 21 are effectively placed in the positioning holes 113.

To sum up, in the probe implanting equipment of the present disclosure, a vibration device (and a vibration controller) is disposed on the base connected to the test socket to effectively position the probes in the positioning holes of the test socket via the vibrations, so as to avoid abnormal quality of manual probe implantation and abnormal problems such as probe stuck and implanted probe deviation, thereby achieving the purpose of manufacturing automation.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A probe implanting equipment, comprising:
a base;
a test socket disposed on the base and having a plurality of positioning holes;
a mouthpiece configuration configured for providing a plurality of probes to the plurality of positioning holes; and
a vibration device disposed on the base.

2. The probe implanting equipment of claim 1, wherein the test socket has a first surface and a second surface opposite to the first surface, and the second surface is fixed on the base.

3. The probe implanting equipment of claim 1, wherein the mouthpiece configuration provides the plurality of probes to the plurality of positioning holes of the test socket by air blowing and probe throwing.

4. The probe implanting equipment of claim 1, further comprising a vibration controller for controlling an action of the vibration device.

5. The probe implanting equipment of claim 4, wherein the vibration controller and the vibration device are integrated with each other or are disposed independently of each other.

6. The probe implanting equipment of claim 4, wherein a user sets multiple control modes by the vibration controller according to a length of the probe or a diameter of the probe of the plurality of probes used to implant into the test socket.

7. The probe implanting equipment of claim 6, wherein the vibration controller selects different voltages according to the length of the probe to control the vibration device to vibrate.

8. The probe implanting equipment of claim 6, wherein the vibration controller selects different amplitudes according to the length of the probe to control the vibration device to vibrate.

9. The probe implanting equipment of claim 6, wherein the vibration controller selects different frequencies according to the diameter of the probe to control the vibration device to vibrate.

10. The probe implanting equipment of claim 6, wherein the vibration controller selects different vibration speeds according to the diameter of the probe to control the vibration device to vibrate.
